(19) United States
(12) Patent Application Publication
(10) Pub. No.: US 2007/0259473 A1
(43) Pub. Date: Nov. 8, 2007

(54) PROCESS TO FORM TFT GATE DIELECTRIC WITH CROSSLINKED POLYMER

(75) Inventors: Yiliang Wu, Mississauga (CA); Ping Liu, Mississauga (CA); Beng S Ong, Mississauga (CA)

Correspondence Address: PATENT DOCUMENTATION CENTER, XEROX CORPORATION, 100 CLINTON AVE., SOUTH, XEROX SQUARE, 20TH FLOOR, ROCHESTER, NY, 14644, US

(73) Assignee: XEROX CORPORATION, Stamford, CT (US)

(21) Appl. No.: 11/611,482

(22) Filed: Dec. 15, 2006

Related U.S. Application Data
(62) Division of application No. 11/104,730, filed on Apr. 13, 2005.

(51) Int. Cl. H01L 21/00

(52) U.S. Cl. 438/82

(57) ABSTRACT

A process for fabricating a thin film transistor including: (a) depositing a gate dielectric precursor composition, wherein the gate dielectric precursor composition includes a polymer comprising polymerized one or more monomers, wherein the one or more monomers includes an optionally substituted vinyl arylalcohol; and (b) irradiating the gate dielectric precursor composition to crosslink the polymer.

### CROSS-REFERENCE TO RELATED APPLICATIONS

This application is a divisional application of co-pending U.S. application Ser. No. 11/104,730 (filing date Apr. 13, 2005) from which priority is claimed, the disclosure of which is totally incorporated herein by reference.

Yiliang Wu et al., U.S. application Ser. No. 10/982,472 (Attorney Docket No. A3392-US-NP), the disclosure of which is totally incorporated herein by reference, published as US 2006/0097360A1.

Ping Liu et al., U.S. application Ser. No. 11/104,728 (Attorney Docket No. 20040824-US-NP), the disclosure of which is totally incorporated herein by reference, published as US 2006/0231908A1.

### STATEMENT REGARDING FEDERALLY SPONSORED RESEARCH OR DEVELOPMENT

This invention was made with United States Government support under Cooperative Agreement No. 70NANBOH3033 awarded by the National Institute of Standards and Technology (NIST). The United States Government has certain rights in the invention.

### BACKGROUND OF THE INVENTION

The present disclosure relates, in various exemplary embodiments, to electronic devices, including microelectronic devices, and processes for making such devices. More specifically, the present disclosure relates to devices including thin film transistors having a gate dielectric, wherein the gate dielectric incorporates a radiation-induced crosslinked polymer comprising polymerized one or more monomers. In embodiments, said one or more monomers of the radiation-induced polymer includes an optionally substituted vinyl arylalcohol.

Thin film transistors are fundamental components in modern-age electronics, including, for example, sensor, imaging, and display devices. Thin film transistor circuits using current mainstream silicon technology may be too costly, particularly for large-area device applications such as backplane switching circuits for displays like active matrix liquid crystal monitors or televisions, where high switching speeds are not essential. The high costs of silicon-based thin film transistor circuits are primarily due to the capital-intensive fabrication facilities and the complex high-temperature, high-vacuum photolithographic fabrication processes under strictly controlled environments.

Because of the cost and complexity of fabricating silicon-based thin film transistor circuits using conventional photolithography processes, there has been an increased interest in plastic thin film transistors which can potentially be fabricated using liquid-based patterning and deposition techniques, such as spin coating, solution casting, dip coating, stencil/screen printing, flexography, gravure, offset printing, ink jet-printing, micro-contact printing, and the like, or a combination of these processes. Such processes are generally simpler and more cost effective compared to the complex photolithographic processes used in fabricating silicon-based thin film transistor circuits for electronic devices. To fabricate liquid-processed thin film transistor circuits, liquid processable materials are therefore required.

Most of the current materials research and development activities for plastic thin film transistors has been devoted to semiconductor materials, particularly liquid-processable organic and polymer semiconductors. On the other hand, other material components such as liquid-processable dielectric materials have not been receiving much attention.

For plastic thin film transistor applications, it is desirable in embodiments to have all the materials be liquid-processable. The use of plastic substrates, together with flexible organic or polymer transistor components can transform the traditional thin film transistor circuits on rigid substrates into mechanically more durable and structurally flexible plastic thin film transistor circuit designs. Flexible thin film transistor circuits will be useful in fabricating mechanically robust and flexible electronic devices. A potential problem addressed by embodiments of the present invention is that a gate dielectric formed using a liquid deposition technique may be adversely affected by the deposition of other layers on top of the gate dielectric.

The following documents provide background information:
Kelley et al., US Patent Application Publication 2003/0102471 A1.
Kelley et al., US Patent Application Publication 2003/0102472 A1.
Kelley et al., U.S. Pat. No. 6,433,359 B1.
Bai et al., US Patent Application Publication 2004/0222412 A1.
F. Garnier et al., “All-Polymer Field-Effect Transistor Realized by Printing Techniques,” Science, Vol. 265, pp. 1684-1686 (Sep. 16, 1994).
S. Y. Park et al., “Cooperative polymer gate dielectrics in organic thin-film transistors,” Appl. Phys. Lett., Vol. 85, No. 12, pp. 2283-2285 (Sep. 20, 2004).
F. Garnier et. al., “Molecular Engineering of Organic Semiconductors: Design of Self-Assembly Properties in Conjugated Thiophene Oligomers,” J. Am. Chem. Soc., Vol. 115, pp. 8716-8721 (1993).
M. Halik et al., “Fully patterned all-organic thin film transistors,” Appl. Phys. Lett., Vol. 81, No. 2, pp. 289-291 (Jul. 8, 2002).
R. Schroeder et. al., “A study of the threshold voltage in pentacene organic field-effect transistors,” Appl. Phys. Lett., Vol. 83, No. 15, pp. 3201-3203 (Oct. 13, 2003).
Z. Bao et. al., “Silsesquioxane Resins as High-Performance Solution Processable Dielectric Materials for Organic Transistor Applications,” Adv. Funct. Mater., Vol. 12, No. 8, pp. 1-6 (August 2002).
J. Veres et al., “Gate Insulators in Organic Field-Effect Transistors,” Chem. Mater. 2004, Vol. 16, pp. 4543-4555 (published on web Sep. 11, 2004).
Lay-Lay Chua et. al., “High-stability ultrathin spin-on benzocyclobutene gate dielectric for polymer field-effect transistors,” Appl. Phys. Lett., Vol. 84, No. 17, pp. 3400-3402 (Apr. 26, 2004).
J. Park et. al., “A polymer gate dielectric for high-mobility polymer thin-film transistors and solvent effects,” Appl. Phys. Lett., Vol. 85, No. 15, pp. 3283-3285 (Oct. 11, 2004).
Z. Turzynski et al., “Influence of diffusion and induced π-bonds on the ultra-violet radiation-initiated crosslinking of polystyrene in solution,” Polymer, Vol. 31, pp. 1500-1506 (August 1990).
K. Kato, “Effect of Molecular Weight on Changes Produced in the Surface Layer of Polystyrene Film in a Nitrogen Atmosphere by Ultraviolet Irradiation, “Journal of Applied Polymer Science,” Vol. 13, pp. 599-606 (1969).

### SUMMARY OF THE DISCLOSURE

There is provided in embodiments a thin film transistor comprising a gate dielectric which includes a radiation-induced crosslinked polymer comprising polymerized one or more monomers, wherein the one or more monomers include an optionally substituted vinyl arylalcohol.

In further embodiments there is provided a thin film transistor comprising:

(a) a semiconductor layer;

(b) a gate electrode;

(c) a source electrode in contact with the semiconductor layer;

(d) a drain electrode in contact with the semiconductor layer; and

(e) a gate dielectric disposed between the semiconductor layer and the gate electrode, wherein the gate dielectric comprises a radiation-induced crosslinked polymer comprising polymerized one or more monomers, wherein the one or more monomers includes an optionally substituted vinyl arylalcohol.

In other embodiments, there is provided a process comprising:

(a) depositing a composition including a polymer comprising polymerized one or more monomers, wherein the one or more monomers includes an optionally substituted vinyl arylalcohol; and

(b) irradiating the composition to crosslink the polymer.

In additional embodiments, there is provided a process for fabricating a thin film transistor comprising:

(a) depositing a gate dielectric precursor composition, wherein the gate dielectric precursor composition includes a polymer comprising polymerized one or more monomers, wherein the one or more monomers includes an optionally substituted vinyl arylalcohol; and

(b) irradiating the gate dielectric precursor composition to crosslink the polymer.

### BRIEF DESCRIPTION OF THE DRAWINGS

Other aspects of the present invention will become apparent as the following description proceeds and upon reference to the following figures which represent exemplary embodiments:

FIG. 1 represents a first embodiment of the present invention in the form of a TFT;

FIG. 2 represents a second embodiment of the present invention in the form of a TFT;

FIG. 3 represents a third embodiment of the present invention in the form of a TFT; and

FIG. 4 represents a fourth embodiment of the present invention in the form of a TFT.

Unless otherwise noted, the same reference numeral in different Figures refers to the same or similar feature.

### DETAILED DESCRIPTION

Generally, a thin film transistor comprises three electrodes (a gate electrode, a source electrode and a drain electrode), a gate dielectric (sometimes referred to as an insulating layer), a semiconductor layer, a supporting substrate, and an optional protecting layer.

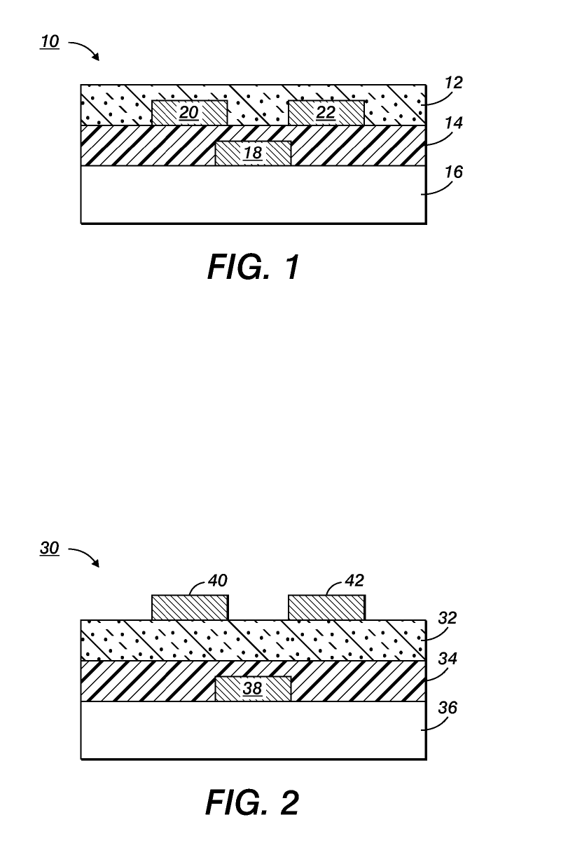

FIGS. 1-4 are illustrative embodiments of suitable thin film transistor structural configurations. FIGS. 1-4 are merely illustrative of possible configurations for the various layers of a thin film transistor and are not intended to be limiting in any manner.

Although specific terms are used in the following description for the sake of clarity, these terms are intended to refer only to the particular structure of the embodiments selected for illustration in the drawings, and are not intended to restrict or limit the scope of the disclosure.

In FIG. 1, there is schematically illustrated an organic thin film transistor (“OTFT”) configuration 10 comprised of a substrate 16, in contact therewith a metal contact 18 (gate electrode) and a layer of a gate dielectric 14 on top of which two metal contacts, source electrode 20 and drain electrode 22, are deposited. Over and between the metal contacts 20 and 22 is an organic semiconductor layer 12 as illustrated herein.

FIG. 2 schematically illustrates another OTFT configuration 30 comprised of a substrate 36, a gate electrode 38, a source electrode 40 and a drain electrode 42, a gate dielectric 34, and an organic semiconductor layer 32.

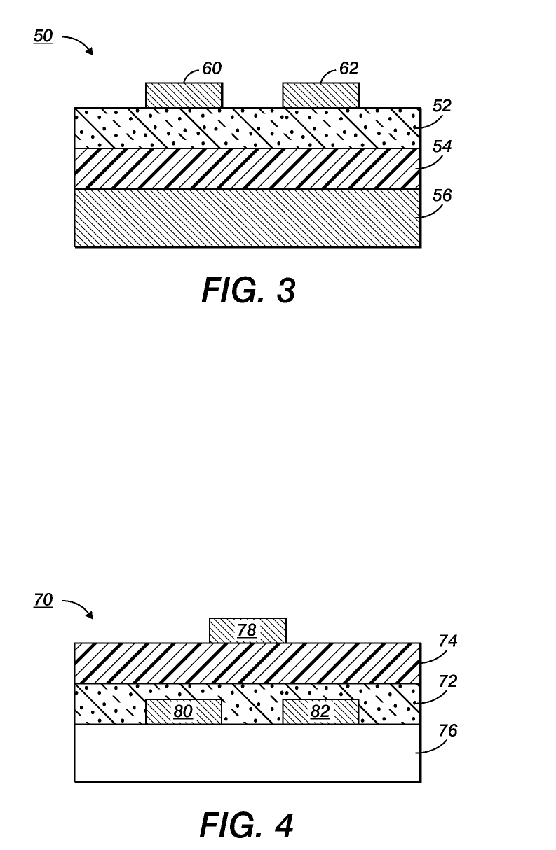

FIG. 3 schematically illustrates a further OTFT configuration 50 comprised of a heavily n-doped silicon wafer 56 which acts as both a substrate and a gate electrode, a gate dielectric 54, and an organic semiconductor layer 52, on top of which are deposited a source electrode 60 and a drain electrode 62.

FIG. 4 schematically illustrates an additional OTFT configuration 70 comprised of substrate 76, a gate electrode 78, a source electrode 80, a drain electrode 82, an organic semiconductor layer 72, and a gate dielectric 74.

In some embodiments of the present disclosure, an optional protecting layer may also be included. For example, such an optional protecting layer may be incorporated on the top of each of the transistor configurations of FIGS. 1-4. The protecting layer may comprise for example silicon oxide, silicon nitride, poly(methyl methyacrylate), polyester, polyimide, or polycarbonate, or a mixture there.

Gate Dielectric

In embodiments, the gate dielectric includes a radiation-induced crosslinked polymer comprising polymerized one or more monomers, wherein the one or more monomers includes an optionally substituted vinyl arylalcohol. In embodiments, the vinyl arylalcohol is unsubstituted. In embodiments, the polymer is a homopolymer of the optionally substituted vinyl arylalcohol. In embodiments, the polymer is a homopolymer of optionally substituted vinyl phenol. More specifically, the polymer is poly(vinyl phenol). In embodiments, the polymer is a copolymer of two or more monomer types, wherein the term copolymer encompasses terpolymer and tetrapolymer. The copolymer can be random, block, or alternating polymer. In other embodiments, the polymer is a copolymer of an optionally substituted vinyl arylalcohol and an acrylate. More specifically, the polymer is a copolymer of a vinylphenol and a methyl methacrylate.

In embodiments, the vinyl arylalcohol is substituted one, two or more times at the vinyl moiety and/or the arylalcohol moiety by substitutent(s) independently selected from the exemplary group consisting of hydrocarbon group, halogen, and heteroatom-containing group.

In embodiments, the optionally substituted vinyl arylalcohol has an exemplary general structure of formula (I): 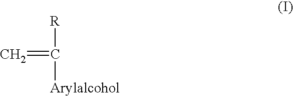
wherein R is hydrogen or an alkyl group (e.g., methyl and ethyl). The arylalcohol groups include for example, phenol, benzyl alcohol, phenylethanol, phenylpropanol, and the like.

In embodiments, the arylalcohol group is a phenol group. The optionally substituted vinyl arylalcohol therefore has in embodiments an exemplary general structure of formula (II): 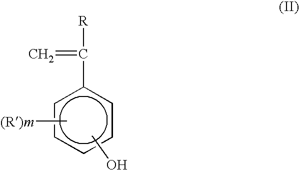
wherein R is the same as defined before; and R′ is independently selected from the exemplary group consisting of hydrogen, hydrocarbon group, halogen, and heteroatom-containing group; m is an integer of 0 to 4.

The hydrocarbon group contains for example from 1 to about 25 carbon atoms, or from 1 to about 10 carbon atoms, and may be for example a straight chain alkyl group, a branched alkyl group, a cycloalkyl group, an aryl group, an alkylaryl group, and an arylalkyl group. Exemplary hydrocarbon groups include for example methyl, ethyl, propyl, butyl, pentyl, hexyl, heptyl, octyl, nonyl, decyl, undecyl, dodecyl, tridecyl, tetradecyl, pentadecyl, cyclopentyl, cyclohexyl, cycloheptyl, and isomers thereof.

The hydrocarbon group is optionally substituted one or more times with for example a halogen (chlorine, bromine, fluorine, and iodine) or a heteroatom containing group described herein, or a mixture thereof.

The heteroatom containing group has for example 2 to about 50 atoms, or from 2 to about 30 atoms) and may be for example a nitrogen containing moiety, an alkoxy group, a heterocyclic system, an alkoxyaryl, and an arylalkoxy. Exemplary heteroatom containing groups include for example cyano, nitro, methoxyl, ethoxyl, and propoxy.

The halogen may be chlorine, bromine, fluorine, and iodine.

Crosslinking the polymer used in the gate dielectric may be advantageous for one or more of the following reasons. First, a crosslinkable gate dielectric offers possibility for patterning of the gate dielectric. The crosslinked portion of the polymer becomes insoluble in solvents, while the uncrosslinked portion of the polymer can be removed using a suitable solvent. Second, a crosslinked gate dielectric may have better mechanical properties. Third, a crosslinked gate dielectric would allow the use of liquid deposition of additional layer or layers without affecting the structural and chemical integrity of the gate dielectric. For example, liquid deposition of a semiconductor layer on top of the gate dielectric would not cause defects in the gate dielectric if the dielectric material is crosslinked and not soluble in the solvent of the semiconductor solution.

In embodiments, the gate dielectric is crosslinked by exposure to an appropriate radiation. Radiation-induced crosslinking is a clean process. The resulting crosslinked gate dielectric usually shows high crosslink density and uniformity in crosslinking throughout the gate dielectric. Radiations that can be utilized for crosslinking include for example ultraviolet irradiation, microwave irradiation, infrared irradiation, X-ray irradiation, and the like, or the combination thereof. In embodiments, the radiation is ultraviolet irradiation with the wavelength ranging for instance from about 200 to about 360 nm, preferably with the wavelength of about 250 nm. Radiation-induced crosslinking could be performed at a relatively low temperature of for example below about 200 degree C., below about 150 degree C., below about 100 degree C., or below about 50 degree C. In embodiments, the radiation-induced crosslinking is carried out at room temperature. Low temperature crosslinking is particularly important for a plastic thin-film transistor as most plastic substrates cannot withstand processing at high temperatures without dimensional distortion or damage. Radiation-induced crosslinking is also a generally fast process, which can be completed in a short time of for example less than about 1 hour, less than about 30 min, or less than about 10 min.

In embodiments, no crosslinking agent is used to form the crosslinked polymer. The use of a crosslinking agent may adversely change the properties of the gate dielectric. In other embodiments, however, a crosslinking agent is used to form the crosslinked polymer. Illustrative crosslinking agents are for example the compounds containing at least two isocyanate groups, compounds containing at least two epoxy groups, compounds containing at least two carboxylic acid groups, and acid anhydrides of carboxylic acid, and a mixture thereof. The weight ratio of the crosslinking agent(s) to the polymer may be for example from about 1:100 to about 40:100.

In embodiments, the gate dielectric is composed primarily or solely of the radiation-induced crosslinked polymer (a residual amount of non-crosslinked polymer used to form the gate dielectric may be present).

In embodiments, the fabrication of the gate dielectric is accomplished by liquid deposition followed by radiation-induced crosslinking. Liquid deposition refers to processes wherein a liquid is used as a vehicle to carry the materials. In embodiments, the liquid may be for example a solvent such as water or an organic solvent. Examples of liquid deposition are spin coating, blade coating, rod coating, screen printing, ink jet printing, stamping and the like. Additional steps may be useful in the fabrication of the gate dielectric in certain embodiments. For example, annealing may be performed after liquid deposition, and rinsing or washing may be performed after radiation-induced crosslinking.

The gate dielectric may be a single layer or may be multilayered. Each layer of the single layer/multilayer gate dielectric has a thickness of for example from about 50 nanometers to about 2 micrometers. In other embodiments each layer of the single layer/multilayer gate dielectric has a thickness of for example from about 200 nanometers to about 1 micrometer. The thickness can be determined by known techniques such as ellipsometry and profilometry. In a multilayer gate dielectric, in embodiments, the layer comprising the radiation-induced crosslinked polymer is disposed closest to the semiconductor layer, compared with the other layer(s) of the multilayer gate dielectric. In other embodiments, in a multilayer gate dielectric, the layer comprising the radiation-induced crosslinked polymer is not in direct contact with the semiconductor layer. Useful materials for the other layer(s) of the multilayer gate dielectric may comprise for example an organic or inorganic electrically insulating material, or combinations thereof. In embodiments, the organic electrically insulating material may comprise of for example polymeric materials such as polyimides, epoxies, polyacrylates, polyvinyls, polyesters, polyethers, the copolymers of the above polymers, and the mixture thereof. The inorganic electrically insulating material may comprise of for example silicon oxide, aluminum oxide, tantalum oxide, titanium oxide, yttrium oxide, hafnium oxide, zirconium oxide, lanthanum oxide, strontiates, tantalates, titanates, zirconates, silicon nitride, zinc selenide, zinc sulfide, and a mixture thereof.

Substrate

The substrate may be composed of for instance silicon, glass plate, plastic film or sheet. For structurally flexible devices, a plastic substrate, such as for example polyester, polycarbonate, polyimide sheets and the like may be preferred. The thickness of the substrate may be from about 10 micrometers to over about 10 millimeters with an exemplary thickness being from about 50 to about 100 micrometers, especially for a flexible plastic substrate and from about 1 to about 10 millimeters for a rigid substrate such as glass plate or silicon wafer.

Electrodes

The gate electrode can be a thin metal film, a conducting polymer film, a conducting film made from conducting ink or paste, or the substrate itself can be the gate electrode, for example heavily doped silicon. Examples of gate electrode materials include but are not restricted to aluminum, gold, chromium, indium tin oxide, conducting polymers such as polystyrene sulfonate-doped poly(3,4-ethylenedioxythiophene) (PSS-PEDOT), conducting ink/paste comprised of carbon black/graphite or colloidal silver dispersion in polymer binders, such as ELECTRODAG™ available from Acheson Colloids Company. The gate electrode layer can be prepared by vacuum evaporation, sputtering of metals or conductive metal oxides, coating from conducting polymer solutions or conducting inks by spin coating, casting or printing. The thickness of the gate electrode layer ranges for example from about 10 to about 200 nanometers for metal films and in the range of about 1 to about 10 micrometers for polymer conductors.

The source and drain electrodes can be fabricated from materials which provide a low resistance ohmic contact to the semiconductor layer. Typical materials suitable for use as source and drain electrodes include those of the gate electrode materials such as gold, nickel, aluminum, platinum, conducting polymers and conducting inks. Typical thicknesses of source and drain electrodes are about, for example, from about 40 nanometers to about 10 micrometers with the more specific thickness being about 100 to about 400 nanometers.

Semiconductor Layer

Materials suitable for use as an organic semiconductor layer include acenes, such as anthracene, tetracene, pentacene, and substituted pentacenes, perylenes, fullerenes, phthalocyanines, oligothiophenes, polythiophenes, and substituted derivatives thereof. In embodiments, the organic semiconductor layer is formed from a liquid processable material. Illustrative examples of suitable semiconductor materials include polythiophenes, oligothiophenes, and the semiconductor polymers described in U.S. application Ser. No. 10/042,342, which is published as U.S. Patent Application No. 2003/0160234, and U.S. Pat. Nos. 6,621,099, 6,774,393, and 6,770,904, the disclosures of which are incorporated herein by reference in their entireties. Additionally, suitable materials include the semiconductor polymers disclosed in “Organic Thin Film Transistors for Large Area Electronics” by C. D. Dimitrakopoulos and P. R. L. Malenfant, Adv. Mater., Vol. 12, No. 2, pp. 99-117 (2002), the disclosure of which is also totally incorporated herein by reference.

The semiconductor layer may be formed by any suitable means including but not limited to vacuum evaporation, spin coating, solution casting, dip coating, stencil/screen printing, flexography, gravure, offset printing, inkjet-printing, micro-contact printing, a combination of these processes, and the like. In embodiments, the semiconductor layer is formed by a liquid deposition method. In embodiments, the semiconductor layer has a thickness of from about 10 nanometers to about 1 micrometer. In further embodiments, the organic semiconductor layer has a thickness of from about 30 to about 150 nanometers. In other embodiments the semiconductor layer has a thickness of from about 40 to about 100 nanometers.

The gate dielectric, the gate electrode, the semiconductor layer, the source electrode, and the drain electrode are formed in any sequence. In embodiments the gate electrode and the semiconductor layer are both in contact with the gate dielectric, and the source electrode and the drain electrode are both in contact with the semiconductor layer. The phrase “in any sequence” includes sequential and simultaneous formation. For example, the source electrode and the drain electrode can be formed simultaneously or sequentially. The composition, fabrication, and operation of field effect transistors are described in Bao et al., U.S. Pat. No. 6,107,117, the disclosure of which is totally incorporated herein by reference.

The invention will now be described in detail with respect to specific exemplary embodiments thereof, it being understood that these examples are intended to be illustrative only and the invention is not intended to be limited to the materials, conditions, or process parameters recited herein. All percentages and parts are by weight unless otherwise indicated. As used herein, room temperature refers to a temperature ranging for example from about 20 to about 25 degrees C.

### EXAMPLE 1

Bottom-gate, top-contact thin film transistors were fabricated. A 10 wt % of poly(vinyl phenol) (PVP) solution in n-butanol solution was filtered through a 0.2-micron syringe filter, and then deposited on n-doped silicon wafer by spin coating. The resultant 750-nm thin film was dried at 60° C. for half hour, and then annealed at 140° C. for 10 min. After cooling down to room temperature, the film was irradiated with an UV light (wavelength, 250 nm) for 20 min. The irradiated film was immersed in n-butanol at 60° C. to remove the unreacted PVP to give a 600-nm crosslinked film after drying. The crosslinked film was very resistant towards solvent attacks by common organic solvents such as toluene, THF, chlorobenzene, or dichlorobenzene. To measure the capacitance, a gold electrode layer was vacuum evaporated on top of the gate dielectric layer. Using a capacitor meter, the capacitance was measured to be 6.4 nF/cm². The dielectric constant of the gate dielectric was calculated to be 4.1.

A polythiophene having the following formula was used as the semiconductor: 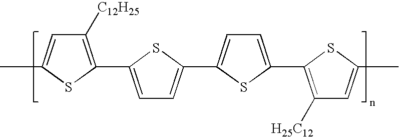
where n is a number of from about 5 to about 5,000. This polythiophene and its preparation are described in Beng Ong et al., US Patent Application Publication No. US 2003/0160230 A1, the disclosure of which is totally incorporated herein by reference. The polythiophene semiconductor layer was deposited on top of the gate dielectric on n-doped silicon wafer substrate by spin coating. The semiconductor layer was dried in a vacuum oven at about 80° C. to about 145° C. for 30 minutes, and then cooled down to room temperature. Subsequently, a set of source/drain electrode pairs were vacuum evaporated on top of the resulting semiconductor layer through a shadow mask to form a series of thin film transistors with various dimensions.

The resulting transistors were evaluated using a Keithley 4200 Semiconductor characterization system. Thin film transistors with channel lengths of about 90 micron and channel widths of about 1000 microns were characterized by measuring the output and transfer curves. The device turned on at around zero volt with a current on/off ratio of 2×10⁴. It is important to note that the off-current was very low, which is almost comparable to that obtained with the TFT using thermally grown silicon oxide as the gate dielectric. Field-effect mobility was calculated to be 0.003 cm²/V.s.

### EXAMPLE 2

In this example, poly(4-vinylphenol-co-methyl methacrylate) was used as the gate dielectric material. Bottom-gate, top-contact TFTs were fabricated using the same procedure as in Example 1. Thin film transistors with channel lengths of about 90 microns and channel widths of about 1000 microns were used for evaluation. The devices showed field-effect mobility of 0.004 cm²/V.s and a current on/off ratio of 4.0×10⁴.

### EXAMPLE 3

A 10 wt % solution of poly(4-vinylphenol-co-methyl methacrylate) in n-butabnol was spin coated on n-doped silicon wafer. The resulting poly(4-vinylphenol-co-methyl methacrylate) layer was crosslinked by exposure to UV radiation according to the procedure of Example 1. An about 50 nm layer of poly(methyl silsesquioxane) was then deposited on top of the crosslinked poly(4-vinylphenol-co-methyl methacrylate) layer then heated at 140-150 degrees C. for 1 hour. Subsequently, the semiconductor layer and the source drain contacts were deposited using the same procedure as in Example 1. Thin film transistors with channel lengths of about 90 microns and channel widths of about 1000 microns were used for evaluation. The devices showed field-effect mobility of 0.12 cm²/V.s and a current on/off ratio of 1.5×10⁵.

### EXAMPLE 4

In this Example, PVP was used the gate dielectric material. The gate dielectric was deposited and UV crosslinked as in Example 1. A 100-nm pentacene semiconductor layer was deposited on the PVP gate dielectric layer by vacuum evaporation at a rate of 0.3 Å per second. Thin film transistors with channel lengths of about 90 microns and channel widths of about 1000 microns were used for evaluation. The TFTs showed field-effect mobility of 0.53 cm² V.s and a current on/off ratio of 5.0×10⁶.

It will be appreciated that various of the above-disclosed and other features and functions, or alternatives thereof, may be desirably combined into many other different systems or applications. Various presently unforeseen or unanticipated alternatives, modifications, variations or improvements therein may be subsequently made by those skilled in the art which are also intended to be encompassed by the following claims. Unless specifically recited in a claim, steps or components of claims should not be implied or imported from the specification or any other claims as to any particular order, number, position, size, shape, angle, color, or material.

1. A process comprising:
(a) depositing a composition including a polymer comprising polymerized one or more monomers, wherein the one or more monomers includes an optionally substituted vinyl arylalcohol; and
(b) irradiating the composition to crosslink the polymer.

2. The process of claim 1, wherein the irradiating the composition comprises using ultraviolet irradiation.

3. The process of claim 1, wherein the depositing the composition comprises using a liquid deposition technique.

4. The process of claim 1, wherein the vinyl arylalcohol is unsubstituted.

5. The process of claim 1, wherein the radiation-induced crosslinked polymer is a radiation-induced crosslinked homopolymer of the optionally substituted vinyl arylalcohol.

6. A process for fabricating a thin film transistor comprising:
(a) depositing a gate dielectric precursor composition, wherein the gate dielectric precursor composition includes a polymer comprising polymerized one or more monomers, wherein the one or more monomers includes an optionally substituted vinyl arylalcohol; and
(b) irradiating the gate dielectric precursor composition to crosslink the polymer.

7. The process of claim 6, wherein the irradiating the gate dielectric precursor composition comprises using ultraviolet irradiation.

8. The process of claim 6, wherein the depositing the gate dielectric precursor composition comprises using a liquid deposition technique.

9. The process of claim 6, wherein the vinyl arylalcohol is unsubstituted.

10. The process of claim 6, wherein the radiation-induced crosslinked polymer is a radiation-induced crosslinked homopolymer of the optionally substituted vinyl arylalcohol.
